(19) United States
(12) Patent Application Publication
(10) Pub. No.: US 2022/0352859 A1
(43) Pub. Date: Nov. 3, 2022

(54) POWER AMPLIFIER MODULE

(71) Applicant: Murata Manufacturing Co., Ltd., Kyoto (JP)

(72) Inventors: Katsuya IKEGAMI, Kyoto (JP); Kazuhiro IKARASHI, Kyoto (JP)

(21) Appl. No.: 17/660,929

(22) Filed: Apr. 27, 2022

(30) Foreign Application Priority Data
Apr. 28, 2021 (JP) 2021-076112

(51) Int. Cl. H03F 3/72; H04B 1/18; H04B 1/00; H03F 3/24

(52) U.S. Cl. CPC H03F 3/72; H04B 1/18; H04B 1/0057; H03F 3/24; H03F 2200/294; H03F 2200/171; H03F 2200/451; H03F 2200/168; H03F 2203/7209

(57) ABSTRACT

An output switch includes; a plurality of input terminals and output terminals each of the plurality of input terminals is electrically connected to at least one of the plurality of output terminals; a first low noise amplifier that amplifies a signal of a predetermined frequency band input through an antenna and outputs a first signal to a first input terminal among the plurality of input terminals, and a second low noise amplifier that amplifies a signal of a predetermined frequency band input through an antenna and outputs a second signal to a second input terminal different from the first input terminal among the plurality of input terminals. A filter that attenuates a signal of a frequency band higher than a frequency band of the second signal is electrically connected between the second input terminal and the second low noise amplifier.

### CROSS REFERENCE TO RELATED APPLICATION

This application claims priority from Japanese Patent Application No. 2021-076112 filed on Apr. 28, 2021. The content of this application is incorporated herein by reference in its entirety.

### BACKGROUND ART

The present disclosure relates to a power amplifier module.

In recent portable terminals, a device conforming to a plurality of frequency bands defined by 3rd Generation Partnership Project (3GPP) has been used as a radio frequency (RF) front end circuit. Furthermore, due to a demand for high-speed communication, multiband systems in which a plurality of frequency bands are used at the same time have been adopted. A technique for performing carrier aggregation (CA) using a frequency band belonging to a mid-band (MB)/high-band(HB) group and a frequency band belonging to a low-band (LB) group is disclosed in WO 2018/123972.

In the disclosure described in WO 2018/123972, when evolved universal terrestrial radio access network-new radio dual connectivity (EN-DC), which is a combination of a frequency band of a fourth generation mobile communication system (hereinafter, referred to as “4G”) and a frequency band of a fifth generation mobile communication system (hereinafter, referred to as “5G”) is, implemented, there is a problem that the size of the system increases.

### BRIEF SUMMARY

The present disclosure reduces the size of a power amplifier module for performing communication using a combination of different frequency bands.

A power amplifier module according to an aspect of the present disclosure includes an output switch that includes a plurality of input terminals and a plurality of output terminals and is capable of electrically connecting each of the plurality of input terminals to at least one of the plurality of output terminals; a first low noise amplifier that amplifies a signal of a predetermined frequency band input through an antenna receiving signals of a plurality of frequency bands and outputs a first signal to a first input terminal among the plurality of input terminals; and a second low noise amplifier that amplifies a signal of a predetermined frequency band input through an antenna receiving signals of a plurality of frequency bands and outputs a second signal to a second input terminal different from the first input terminal among the plurality of input terminals. A filter that attenuates a signal of a frequency band higher than a frequency band of the second signal is electrically connected between the second input terminal and the second low noise amplifier.

Furthermore, a power amplifier module according to an aspect of the present disclosure includes a first low noise amplifier that amplifies a first reception signal of a predetermined frequency band input through an antenna capable of receiving signals of a plurality of frequency bands and outputs the amplified first reception signal to a first input terminal among a plurality of input terminals of an output switch; a second low noise amplifier that amplifies a second reception signal of a predetermined frequency band input through an antenna receiving signals of a plurality of frequency bands and outputs the amplified second reception signal to a second input terminal different from the first input terminal among the plurality of input terminals of the output switch; a first input switch that includes a first input terminal to which a signal of a first frequency band is input, a second input terminal to which a signal of a second frequency band higher than the first frequency band is input, and a first output terminal connected to the first low noise amplifier, the signals input to the first input terminal and the second input terminal being among the signals received at the antenna that receives the signals of the plurality of frequency bands and input through demultiplexers that split a plurality of frequency bands provided in a same module as a module in which the output switch is provided, and is capable of electrically connecting the first input terminal or the second input terminal to the first output terminal; and a second input switch that includes a third input terminal to which a signal of a third frequency band lower than the first frequency band is input and a second output terminal connected to the second low noise amplifier, the signal input to the third input terminal being among the signals received at the antenna that receives the signals of the plurality of frequency bands and input through demultiplexers that split a plurality of frequency bands provided in a module different from the module in which the output switch is provided, and is capable of electrically connecting the third input terminal to the second output terminal. The first frequency band includes part of the third frequency band.

Furthermore, a power amplifier module according to an aspect of the present disclosure includes a first low noise amplifier that amplifies a first reception signal of a predetermined frequency band input through an antenna capable of receiving signals of a plurality of frequency bands and outputs the amplified first reception signal to a first input terminal among a plurality of input terminals of an output switch; a second low noise amplifier that amplifies a second reception signal of a predetermined frequency band input through an antenna receiving signals of a plurality of frequency bands and outputs the amplified second reception signal to a second input terminal different from the first input terminal among the plurality of input terminals of the output switch; a first switch that includes a first input terminal to which a signal of a first frequency band is input, a second input terminal to which a signal of a second frequency band higher than the first frequency band is input, and a first output terminal connected to the first low noise amplifier, the signals input to the first input terminal and the second input terminal being among the signals received at the antenna that receives the signals of the plurality of frequency bands and input through demultiplexers that split a plurality of frequency bands provided in a same module as a module in which the output switch is provided, and is capable of electrically connecting the first input terminal or the second input terminal to the first output terminal; and a second input switch that includes a third input terminal to which a signal of a third frequency band lower than the first frequency band is input, a fourth input terminal to which a signal of the first frequency band is input, and a second output terminal connected to the second low noise amplifier, the signals input to the third input terminal and the fourth input terminal being among the signals received at the antenna that receives the signals of the plurality of frequency bands and input through demultiplexers that split a plurality of frequency bands provided in a module different from the module in which the output switch is provided, and is capable of electrically connecting the third input terminal to the second output terminal. Signals of different frequency bands based on a combination of the first frequency band and the third frequency band, a combination of the second frequency band and the third frequency band, and a combination of the first frequency band and the second frequency band are able to be received at the same time.

According to the present disclosure, the size of a power amplifier module for performing communication using a combination of different frequency bands can be reduced.

### BRIEF DESCRIPTION OF THE DRAWINGS

FIG. 1 is a diagram illustrating an overview of a configuration of a power amplifier module according to an embodiment;

FIG. 2 is a graph illustrating an example of a first signal attenuated by a filter circuit;

FIG. 3 is a diagram illustrating an example of an operation of an output switch;

FIG. 4 is a diagram illustrating an example of a configuration of a power amplifier module according to a first modification;

FIG. 5 is a diagram illustrating part of a configuration of a power amplifier module according to a second modification;

FIG. 6 is a diagram illustrating an example of a configuration of a filter circuit according to the second modification;

FIG. 7 is a graph illustrating an example of attenuation of a second-order harmonic wave of a transmission band of BAND 8 included in a first signal in the filter circuit;

FIG. 8 is a graph illustrating an example of attenuation of a second-order harmonic wave of a transmission band of BAND 12 included in the first signal in the filter circuit;

FIG. 9 is a diagram illustrating an example of a configuration in which filter circuits are provided on an output terminal side of an output switch;

FIG. 10 is a graph illustrating an example of a second-order harmonic wave of a first transmission band and a second-order harmonic wave of a second transmission band that are attenuated in a filter circuit;

FIG. 11 is a diagram illustrating an example of an operation for the case where an output switch is not a full matrix switch;

FIG. 12 is a graph illustrating an example of loss of a first signal for the case where a filter circuit is provided on an output terminal side of an output switch;

FIG. 13 is a diagram illustrating an example of a state in which a filter circuit is not provided at an appropriate position in a power amplifier module;

FIG. 14 illustrates attenuation of second-order harmonic waves of a first signal of BAND 8 and BAND 12 in a filter circuit that is not capable of adjusting a frequency band to be attenuated;

FIG. 15 is a diagram illustrating an overview of a configuration of a power amplifier module according to a second embodiment;

FIG. 16 is a table illustrating an example of combinations of frequency bands in the second embodiment;

FIG. 17 is a diagram illustrating an overview of a configuration of a power amplifier module according to a first comparative example;

FIG. 18 is a table illustrating an example of combinations of frequency bands in the first comparative example;

FIG. 19 is a diagram illustrating an overview of a configuration of a power amplifier module according to a second comparative example; and

FIG. 20 is a table illustrating an example of combinations of frequency bands in the second comparative example.

### DETAILED DESCRIPTION

Hereinafter, embodiments of the present disclosure will be described with reference to drawings. Circuit elements with the same signs represent the same circuit elements, and redundant explanation will be omitted.

Power amplifier module 100 according to first embodiment

### Configuration

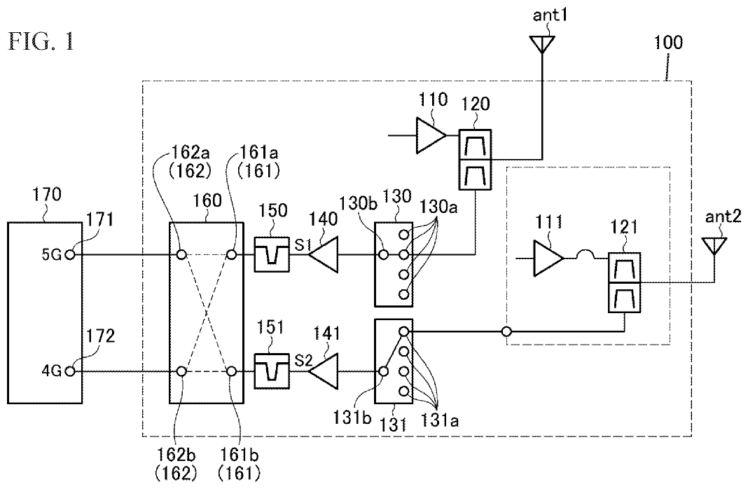

An overview of a power amplifier module 100 according to a first embodiment will be described with reference to FIG. 1. FIG. 1 is a diagram illustrating an overview of a configuration of the power amplifier module 100 according to the first embodiment. For example, the power amplifier module 100 is mounted on a mobile communication device such as a cellular phone. The power amplifier module 100 amplifies the power of an input signal RFin to a level that is suitable for the input signal RFin to be transmitted to a base station, and outputs the amplified signal as an amplification signal RFout. The input signal RFin is, for example, a radio frequency (RF) signal modulated in accordance with a predetermined communication method by a radio frequency integrated circuit (RFIC) or the like. Furthermore, the power amplifier module 100 receives, for example, a reception signal of a predetermined frequency band from the base station. Communication standards for the input signal RFin and the reception signal include, for example, a second generation mobile communication system (2G), a third generation mobile communication system (3G), a fourth generation mobile communication system (4G), a fifth generation mobile communication system (5G), 5G new radio (5G NR), long term evolution-frequency division duplex (LTE-FDD), LTE-time division duplex (LTE-TDD), LTE-Advanced, LTE-Advanced Pro, and so on. The input signal RFin and the reception signal each has a frequency ranging from about several hundreds MHz to about several tens GHz. However, communication standards for the input signal RFin and the reception signal and frequencies of the input signal RFin and the reception signal are not limited to those mentioned above.

A known system (for example, the system described in WO 2018/123972) includes a low noise amplifier that amplifies a reception signal of a frequency band belonging to the MB/HB group and a low noise amplifier that amplifies a reception signal of a frequency band belonging to the LB group, which is different from the MB/HB group. For example, the system implements CA using the frequency band belonging to the MB/HB group and the frequency band belonging to the LB band. In the system, however, a frequency band of a signal output from each of the low noise amplifiers is fixed to a single band. Thus, in the system, in order to implement evolved universal terrestrial radio access network new radio dual connectivity (EN-DC) that supports 4G and 5G frequency bands, a module needs to be additionally installed for each frequency band. Thus, there is a problem that the size of the system increases.

Meanwhile, for example, to improve throughput, a portable terminal supporting 5G (non-stand-alone mode) implements EN-DC that supports a combination of 5G and 4G frequency bands. For example, with EN-DC, one or more antennas receive signals of a plurality of frequency bands. With EN-DC, the received signals of the plurality of frequency bands are separated according to the frequency bands, and simultaneous communications of the separated reception signals can be performed. Hereinafter, for example, in a communication apparatus including the power amplifier module 100 mounted thereon, each of two antennas respectively receives both of a 5G frequency band and a 4G frequency band. In the communication apparatus, in the case where one antenna receives a signal of a 5G frequency band, the other antenna receives a signal of a 4G frequency band.

A configuration of the power amplifier module 100 will be described in detail with reference to FIG. 1. As illustrated in FIG. 1, for example, the power amplifier module 100 includes an amplifier 110, an amplifier 111, a duplexer 120, a duplexer 121, an input switch 130, an input switch 131, a low noise amplifier 140, a low noise amplifier 141, a filter circuit 150, a filter circuit 151, and an output switch 160. The amplifier 111 and the duplexer 121 are not necessarily formed in the same module as the power amplifier module 100 and may be formed in a module different from the power amplifier module 100. Hereinafter, for the sake of convenience, explanation will be provided based on the assumption that the amplifier 111 and the duplexer 121 are formed in the different module.

The amplifier 110 is, for example, a circuit that amplifies the power level of an input signal RFin1 and outputs an amplification signal RFout1. The amplifier 110 may be, for example, an amplifier supporting an input signal RFin1 of a 5G frequency band and an input signal RFin1 of a 4G frequency band. The amplifier 110 is connected to an antenna (hereinafter, referred to as a “first antenna ant1”) with the duplexer 120, which will be described later, interposed therebetween. The amplifier 111 is a circuit that amplifies the power level of an input signal RFin2 and outputs an amplification signal RFout2. The amplifier 111 is connected to an antenna (hereinafter, referred to as a “second antenna ant2”) with the duplexer 121, which will be described later, interposed therebetween.

The duplexer 120 is, for example, a filter circuit that sorts signals into a signal (hereinafter, referred to as a “first transmission signal”) of a predetermined frequency band output from the amplifier 110 and a signal (hereinafter, referred to as a “first reception signal”) of a predetermined frequency band received at the first antenna ant1. For example, the duplexer 120 is electrically connected between a switch (not illustrated in FIG. 1) connected to the first antenna ant1 and the input switch 130, which will be described later. The duplexer 121 has a function similar to the function of the duplexer 120. The duplexer 121 is electrically connected between a switch (not illustrated in FIG. 1) connected to the second antenna ant2 and the input switch 131, which will be described later. Hereinafter, a signal of a predetermined frequency band output from the amplifier 111 may be referred to as a “second transmission signal” and a signal of a predetermined frequency band received at the second antenna ant2 may be referred to as a second reception signal. Although the duplexer 120 and the duplexer 121 are each illustrated as a single device in FIG. 1, the duplexer 120 and the duplexer 121 are not limited to those illustrated in FIG. 1. The duplexer 120 may be configured to be multiple devices associated with frequency bands of signals received at the first antenna ant1. The duplexer 121 may be configured in a similar manner. Furthermore, for example, in the case of a TDD communication method, the power amplifier module 100 does not necessarily include the duplexer 120 or the duplexer 121 and may include band pass filters in place of the duplexers 120 and 121.

The input switch 130 is, for example, a switch including a plurality of input terminals 130a and an output terminal 130b. The input terminals 130a are, for example, terminals that are connected to the duplexer 120 or the duplexer 121 and receive reception signals. The output terminal 130b is, for example, a terminal that is connected to the low noise amplifier 140, which will be described later. The input switch 130 electrically connects any one of the plurality of input terminals 130a to the output terminal 130b. The input switch 131 has a configuration similar to the configuration of the input switch 130. An output terminal 131b is, for example, a terminal that is connected to the low noise amplifier 141, which will be described later.

For example, the low noise amplifiers 140 and 141 amplify signals of predetermined frequency bands input via the first antenna ant1 and the second antenna ant2 that are capable of receiving signals of a plurality of frequency bands and output the amplified signals to the output switch 160, which will be described later. Hereinafter, for the sake of convenience, a signal amplified and output by the low noise amplifier 140 may be referred to as a “signal S1”, and a signal amplified and output by the low noise amplifier 141 may be referred to as a “signal S2”. The signal S1 may contain a high-order harmonic wave of a first transmission signal output from the amplifier 110 as well as a first reception signal. More particularly, the signal S1 may contain a high-order harmonic wave of the first transmission signal generated by distortion of the first transmission signal that has flowed into the low noise amplifier 140. Similarly, for example, the signal S2 may contain a second transmission signal output from the amplifier 111 as well as a second reception signal. Furthermore, the signal S2 may contain a high-order harmonic wave of the second transmission signal generated by distortion of the second transmission signal that has flowed into the low noise amplifier 141.

For example, the low noise amplifier 140 amplifies a signal of a predetermined frequency band and outputs the signal S1. Hereinafter, for the sake of convenience, the predetermined frequency band of the signal amplified by the low noise amplifier 140 will be referred to as a “first band”. The first band represents, for example, frequency bands including BAND 8, BAND 20, and BAND 28 of a frequency band of the first reception signal (hereinafter, referred to as a “reception band”) and a frequency band of the first transmission signal (hereinafter, referred to as a “transmission band”). Hereinafter, for the sake of convenience, in the low noise amplifier 140, the reception band may be referred to as a “first reception band” and the transmission band may be referred to as a “first transmission band”. BAND 8, BAND 20, and BAND 28 represent frequency bands approved by the 3rd Generation Partnership Project (3GPP). For BAND 8, for example, the reception band ranges from 925 MHz to 960 MHz, and the transmission band ranges from 880 MHz to 915 MHz. For BAND 20, for example, the reception band ranges from 832 MHz to 862 MHz, and the transmission band ranges from 832 MHz to 862 MHz. For BAND 28, for example, the reception band ranges from 703 MHz to 748 MHz, and the transmission band ranges from 703 MHz to 748 MHz. The first band is not limited to the frequency bands of the BANDs mentioned above and may include frequency bands of desired BANDs. For example, the first band may include frequency bands ranging from 3.3 GHz to 4.2 GHz, ranging from 4.4 GHz to 5.0 GHz, ranging from 24.25 GHz to 29.5 GHz, and the like.

For example, the low noise amplifier 141 amplifies a signal of a predetermined frequency band and outputs the signal S2. Hereinafter, for the sake of convenience, the predetermined frequency band of the signal amplified by the low noise amplifier 141 will be referred to as a “second band”. As with the first band, for example, the second band may include a reception band of a reception signal and a transmission band of a transmission signal. Hereinafter, for the sake of convenience, in the low noise amplifier 141, the reception band may be referred to as a “second reception band”, and the transmission band may be referred to as a “second transmission band”. For example, the second band may represent a frequency band different from the first band or may represent the same frequency band as the first band. That is, the low noise amplifier 140 may be an amplifier supporting a frequency band of BAND 8, and the low noise amplifier 141 may be an amplifier supporting frequency bands of BAND 20 and BAND 28. Furthermore, the low noise amplifier 140 and the low noise amplifier 141 may be amplifiers supporting the same frequency band (for example, ranging from 600 MHz to 1000 MHz, which is a full low band).

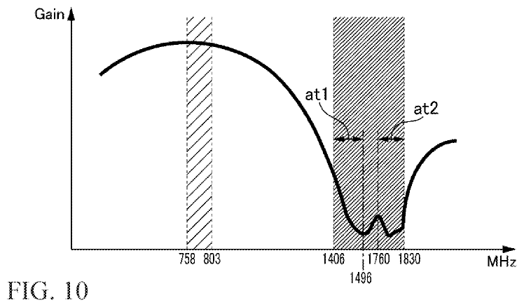

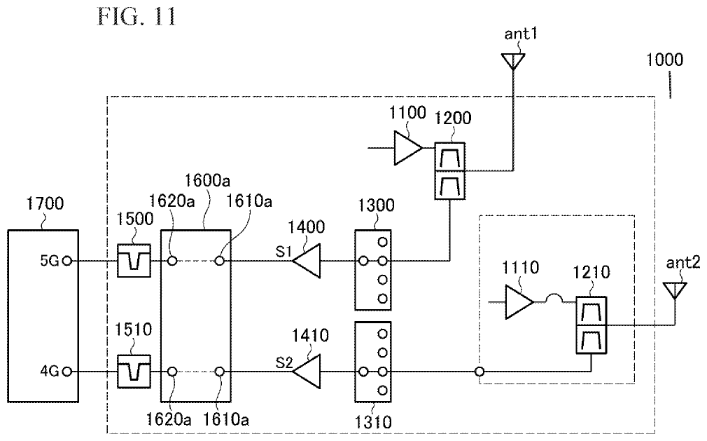

The filter circuits 150 and 151 are, for example, circuits that attenuate signals of predetermined frequency bands. The filter circuits 150 and 151 may be, for example, low pass filters, band pass filters, band elimination filters, or high pass filters. Hereinafter, for example, a case where the filter circuits 150 and 151 are circuits that attenuate signals of frequency bands higher than predetermined frequency bands will be explained. Specifically, the filter circuit 150 may be, for example, a circuit that attenuates a signal of a frequency band that is an integral multiple of (in this example, double) the first band. The filter circuit 150 is electrically connected between the low noise amplifier 140 and the output switch 160, which will be described later. Thus, the power amplifier module 100 can attenuate a harmonic wave signal that is double the first band (for example, the first transmission band) of the signal S1 output from the low noise amplifier 140. Furthermore, the filter circuit 151 may be a circuit that attenuates a signal of a frequency band that is an integral multiple of (in this example, double) the second band (for example, the second transmission band). The filter circuit 151 is electrically connected between the low noise amplifier 141 and the output switch 160, which will be described later. As described above, with the filter circuits 150 and 151 provided between the low noise amplifiers 140 and 141 and the output switch 160, the sizes of the filter circuits 150 and 151 can be reduced. This will be described in detail later with reference to FIG. 10.

The output switch 160 includes, for example, a plurality of input terminals 161 and a plurality of output terminals 162. The output switch 160 is, for example, a full matrix switch that is capable of electrically connecting each of the plurality of input terminals 161 to at least one of the plurality of output terminals 162. The low noise amplifier 140 is connected to an input terminal 161a of the plurality of input terminals 161 with the filter circuit 150 interposed therebetween. The low noise amplifier 141 is connected to an input terminal 161b of the plurality of input terminals 161 with the filter circuit 151 interposed therebetween. An output terminal 162a of the plurality of output terminals 162 is connected to an input terminal 171 of a high-frequency integrated circuit 170. An output terminal 162b of the plurality of output terminals 162 is connected to an input terminal 172 of the high-frequency integrated circuit 170. For example, the input terminal 171 may be connected to a circuit (not illustrated in FIG. 1) that processes a signal of a frequency band of 5G. For example, the input terminal 172 may be connected to a circuit (not illustrated in FIG. 1) that processes a signal of a frequency band of 4G. Furthermore, each of the input terminal 171 and the input terminal 172 may support both 4G and 5G. For example, the output switch 160 allows a predetermined input terminal 161 to be connected to a predetermined output terminal 162 in accordance with operation of the input switch 130 and the input switch 131. Specifically, in the case where the frequency band of the signal S1 supports 5G, the output switch 160 allows the input terminal 161a to be connected to the output terminal 162a in accordance with an operation for connecting the output terminal 130b of the input switch 130 to an input terminal 130a corresponding to the frequency band of the signal S1. Furthermore, in the case where the frequency band of the signal S1 supports 4G, the output switch 160 allows the input terminal 161a to be connected to the output terminal 162b in accordance with an operation for connecting the output terminal 130b of the input switch 130 to an input terminal 130a corresponding to the frequency band of the signal S1. Furthermore, in the case where the frequency band of the signal S2 supports 4G, the output switch 160 allows the input terminal 161b to be connected to the output terminal 162b in accordance with an operation for connecting the output terminal 131b of the input switch 131 to an input terminal 131a corresponding to the frequency band of the signal S2. Furthermore, in the case where the frequency band of the signal S2 supports 5G, the output switch 160 allows the input terminal 161b to be connected to the output terminal 162a in accordance with an operation for connecting the output terminal 131b of the input switch 131 to an input terminal 131a corresponding to the frequency band of the signal S2. As described above, with the use of the output switch 160 configured to be a full matrix switch, each of the first antenna ant1 and the second antenna ant2 is capable of receiving signals of frequency bands of 5G and 4G.

<Operation>

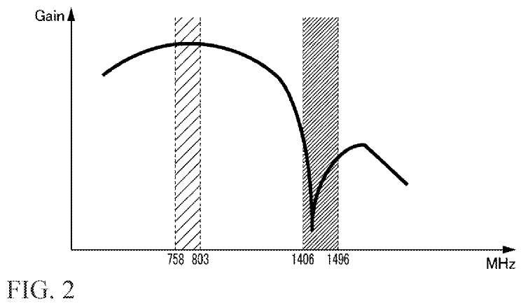

An operation of the power amplifier module 100 will be described with reference to FIGS. 1 and 2. Hereinafter, for example, the first band including the first reception band and the first transmission band of the low noise amplifier 140 is defined ranging from 700 MHz to 800 MHz (hereinafter, may be referred to as “BAND 28”), and the second band including the second reception band and the second transmission band of the low noise amplifier 141 is defined ranging from 800 MHz to 1000 MHz (hereinafter, may be referred to as “BAND 8”). Furthermore, BAND 8 is defined as a frequency band of 4G, and BAND 28 is defined as a frequency band of 5G. BAND 8 and BAND 28 are merely examples. For example, the first band may range from 3.3 GHz to 4.2 GHz, and the second band may range from 4.4 GHz to 5.0 GHz. A combination of bands (frequency bands) is not limited. Furthermore, hereinafter, to explain effectiveness of the power amplifier module 100 according to the first embodiment, explanation will be given with reference to FIGS. 9 to 11 in an appropriate manner.

First, as illustrated in FIG. 1, the first antenna ant1 receives a signal of the first reception band (for example, 758 MHz to 803 MHz). The second antenna ant2 receives a signal of the second reception band (for example, 925 MHz to 960 MHz). The signal received at the first antenna ant1 is input via the duplexer 120 to the input switch 130. The low noise amplifier 140 amplifies a signal output from the output terminal 130b of the input switch 130 and outputs a signal S1. The low noise amplifier 140 outputs the signal S1 through the filter circuit 150 to the output switch 160. At this time, for example, the filter circuit 150 attenuates a second-order harmonic wave, which is included in the signal S1, of the first transmission band (BAND 28: 703 MHz to 748 MHz) that has flowed from the amplifier 110 through the duplexer 120. In a similar manner, for example, the filter circuit 151 attenuates a second-order harmonic wave, which is included in the signal S2, of the second transmission band (BAND 8: 880 MHz to 915 MHz) that has flowed from the amplifier 111 through the duplexer 121. The filter circuit 150 does not necessarily attenuate the second-order harmonic wave of the first transmission band and may attenuate a harmonic wave that is an integral multiple of the first transmission band. The same applies to the filter circuit 151. Hereinafter, a case where the second-order harmonic wave of the first transmission band is attenuated by the filter circuit 150 will be described, and then effectiveness of this case will be explained by comparing the case with a comparative example.

FIG. 2 illustrates attenuation of the second-order harmonic wave of the first transmission band included in the signal S1 in the filter circuit 150. FIG. 2 is a graph illustrating an example of the signal S1 attenuated by the filter circuit 150. In FIG. 2, an x axis represents frequency, and a y axis represents gain. As illustrated in FIG. 2, the filter circuit 150 is configured to attenuate the second-order harmonic wave of the first transmission band (for example, 1406 MHz to 1496 MHz) included in the same band as a band of the first reception band (BAND 28: 758 MHz to 803 MHz) included in the first band. In a similar manner, although not illustrated in FIG. 2, the filter circuit 151 may be configured to attenuate the second-order harmonic wave of the second transmission band (for example, 1600 MHz to 1830 MHz) included in the same band as a band of the second reception band (BAND 8: 925 MHz to 960 MHz) included in the second band. That is, the filter circuit 150 may be configured to attenuate the second-order harmonic wave of the first transmission band, and the filter circuit 151 may be configured to attenuate the second-order harmonic wave of the second transmission band. Thus, the power amplifier module 100 can achieve appropriate attenuation of a harmonic wave in a compact resonant circuit.

A case where filter circuits are provided on an output terminal side of an output switch will be described below with reference to FIGS. 9 and 10. FIG. 9 is a diagram illustrating an example of a configuration in which filter circuits 1500 and 1510 are provided on an output terminal 1620 side of an output switch 1600. As illustrated in FIG. 9, for example, the second-order harmonic wave of the first transmission band (for example, 1406 MHz to 1496 MHz) of the same band as a band of the first reception band (BAND 28: 758 MHz to 803 MHz) included in the first band and the second-order harmonic wave of the second transmission band (for example, 1760 MHz to 1830 MHz) of the same band as a band of the second reception band (BAND 8: 925 MHz to 960 MHz) are input to the filter circuit 1500. This is because the signal S2 output from a low noise amplifier 1410 may be output through the output switch 1600 to the output terminal 1620. That is, the filter circuit 1500 needs to attenuate the second-order harmonic wave of the first transmission band of the same band as a band of the first reception band and the second-order harmonic wave of the second transmission band of the same band as a band of the second reception band. Thus, the filter circuit 1500 needs, for example, more resonant circuits than that in the filter circuit 150. The same applies to the filter circuit 1510. A case where the second-order harmonic wave of the first transmission band and the second-order harmonic wave of the second transmission band are attenuated by the filter circuit 1500 will be described with reference to FIG. 10. FIG. 10 is a graph illustrating an example of the second-order harmonic wave of the first transmission band and the second-order harmonic wave of the second transmission band that are attenuated by the filter circuit 1500. In FIG. 10, an x axis represents frequency, and a y axis represents gain. As illustrated in FIG. 10, the filter circuit 1500 attenuates a signal of the second-order harmonic wave of the first transmission band (1406 MHz to 1496 MHz) (“at1” in FIG. 10) and the second-order harmonic wave of the second transmission band (1760 MHz to 1830 MHz) (“at2” in FIG. 10). In a similar manner, although not illustrated in FIG. 10, for example, the second-order harmonic wave of the first transmission band and the second-order harmonic wave of the second transmission band are input to the filter circuit 1510, and the filter circuit 1510 attenuates a signal of these second-order harmonic waves. That is, the filter circuit 1500 and the filter circuit 1510 each needs more resonant circuits than that in the filter circuit 150.

Referring back to FIG. 1, the output switch 160 then connects, in accordance with the frequency band of the signal S1, an input terminal 161 to an output terminal 162 that is to output the signal S1. In this example, the output switch 160 connects the input terminal 161a to the output terminal 162b so that the signal S1 of the frequency band of 4G input to the input terminal 161a will be output from the output terminal 162b. The high-frequency integrated circuit 170 acquires, through the input terminal 172 corresponding to 4G, the signal S1 output from the output terminal 162b of the output switch 160. In a similar manner, the output switch 160 connects, in accordance with the frequency band of the signal S2, an input terminal 161 to an output terminal 162 that is to output the signal S2. In this example, the output switch 160 connects the input terminal 161b to the output terminal 162a so that the signal S2 of the frequency band of 5G input to the input terminal 161b will be output from the output terminal 162a. The high-frequency integrated circuit 170 acquires, through the input terminal 171 corresponding to 5G, the signal S2 output from the output terminal 162a of the output switch 160.

Operations of the output switch 160 performed in the case where the first antenna ant1 and the second antenna ant2 each receives signals (for example, 700 MHz to 1000 MHz) of 4G (in this case, BAND 8) and 5G (in this case BAND 28) will be described. In this case, the low noise amplifier 140 and the low noise amplifier 141 are amplifiers supporting ranging from 700 MHz to 1000 MHz. For example, in the case where the first antenna ant1 receives a 5G signal and the second antenna ant2 receives a 4G signal, the output switch 160 connects the output terminal 162a to the input terminal 161a, and connects the output terminal 162b to the input terminal 161b. In contrast, in the case where the first antenna ant1 receives a 4G signal and the second antenna ant2 receives a 5G signal, the output switch 160 connects the output terminal 162b to the input terminal 161a, and connects the output terminal 162a to the input terminal 161b. As described above, with the use of the output switch 160 configured to be a full matrix switch, the first antenna ant1 and the second antenna ant2 are each capable of receiving 4G and 5G signals.

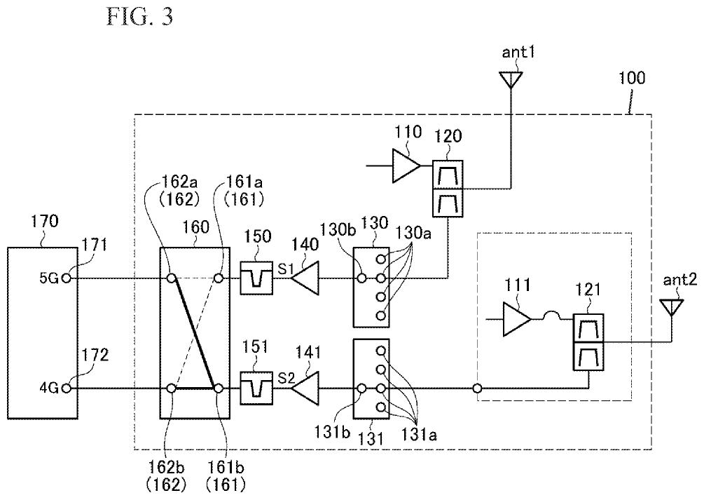

Next, another example of effectiveness of the case where the output switch 160 is configured to be a full matrix switch will be described with reference to FIG. 3. FIG. 3 is a diagram illustrating an example of an operation of the output switch 160. As illustrated in FIG. 3, in the case where only one antenna (in this example, the second antenna ant2) receives 4G and 5G signals at the same time, the output switch 160 connects both the output terminal 162a and the output terminal 162b to the input terminal 161b at the same time. That is, the power of the signal S2 input to the input terminal 161b is split into halves, and the split signals are output from the output terminal 162a and the output terminal 162b. In this case, the high-frequency integrated circuit 170 splits a signal into a 4G signal and a 5G signal. As described above, with the use of the output switch 160 configured to be a full matrix switch, a single antenna is capable of receiving 4G and 5G signals.

In contrast, a case where an output switch is not a full matrix switch will be described below with reference to FIG. 11. FIG. 11 is a diagram illustrating an example of an operation for the case where an output switch 1600a is not a full matrix switch. As illustrated in FIG. 11, in the case where the output switch 1600a is not a full matrix switch, the signal S1 output from a low noise amplifier 1400 is input, through the filter circuit 1500, to an input terminal 1710 of a high-frequency integrated circuit 1700. That is, the signal S1 output from the low noise amplifier 1400 needs to be a signal of 5G. Thus, the first antenna ant1 connected to the low noise amplifier 1400 can only receive a signal of 5G. In a similar manner, the second antenna ant2 connected to the low noise amplifier 1410 can only receive a signal of 4G. As described above, in the case where the output switch 1600a is not a full matrix switch, signals of frequency bands of 4G and 5G cannot be received by a single antenna. Furthermore, in the case where 4G and 5G signals are received by a single antenna without necessarily using a full matrix switch, there is a problem that a large-scale switch, such as an output switch of multiple stages, is required.

### First Modification

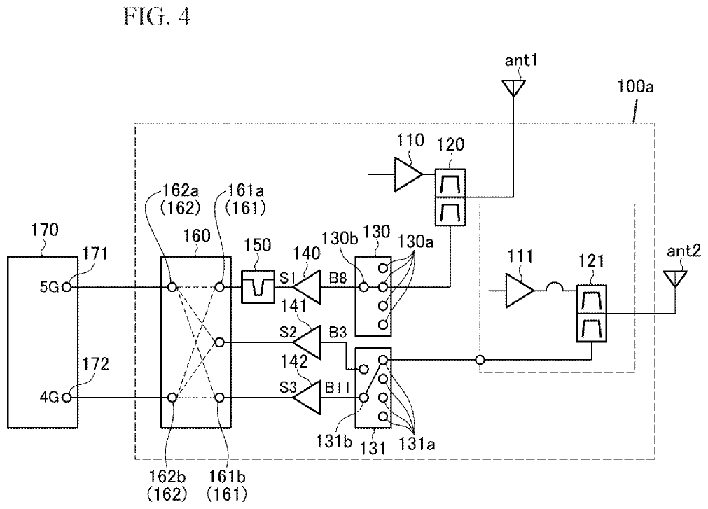

Next, a modification of a power amplifier module 100a will be described with reference to FIG. 4. FIG. 4 is a diagram illustrating an example of a configuration of the power amplifier module 100a according to a first modification. As illustrated in FIG. 4, the power amplifier module 100a is different from the power amplifier module 100 according to the first embodiment in that the low noise amplifier 141 and a low noise amplifier 142 are connected to the output terminal 131b of the input switch 131. Furthermore, in the power amplifier module 100a, the filter circuit 150 is connected only to the low noise amplifier 140 among the low noise amplifier 140, the low noise amplifier 141, and the low noise amplifier 142. Hereinafter, for example, the signal S1 output from the low noise amplifier 140 contains a second-order harmonic wave (for example, 1760 MHz to 1830 MHz) of BAND 8 (for example, 880 MHz to 915 MHz in the transmission band). Furthermore, for example, the signal S2 amplified by the low noise amplifier 141 includes a frequency band of BAND 3 (for example, 1805 MHz to 1880 MHz in the reception band). Furthermore, for example, a signal amplified by the low noise amplifier 142 (hereinafter, referred to as a “signal S3”) includes a frequency band of BAND 11 (for example, 1475.9 MHz to 1495.9 MHz in the reception band). Hereinafter, only features different from the power amplifier module 100 will be described.

As illustrated in FIG. 4, in the power amplifier module 100a, the filter circuit 150 is provided between the low noise amplifier 140 and the output switch 160. The filter circuit 150 attenuates a harmonic wave signal, which is included in the signal S1, that is an integral multiple of (in this example, double) the first transmission band (in this example, the transmission band of BAND 8). Thus, the filter circuit 150 reduces interference on the signal S2 (BAND 3) included in the frequency band that is double the first transmission band (the transmission band of BAND 8) by the second-order harmonic wave of the signal of the first transmission band. That is, in the power amplifier module 100a, no filter circuit is provided between a low noise amplifier for a frequency band not interfering with a high-order harmonic wave (harmonic wave distortion) of a signal output from another low noise amplifier and the output switch 160. Specifically, since the low noise amplifier 141 is an amplifier supporting BAND 3 (1805 MHz to 1880 MHz in the reception band), a high-order harmonic wave that is an integral multiple of BAND 3 does not interfere with frequency bands (BAND 8 and BAND 11) for the other low noise amplifiers 140 and 142. Thus, there is no need to provide a filter circuit between the low noise amplifier 141 and the output switch 160. In a similar manner, since the low noise amplifier 142 is an amplifier supporting BAND 11, a high-order harmonic wave that is an integral multiple of BAND 11 does not interfere with frequency bands (BAND 3 and BAND 8) for the other low noise amplifiers 140 and 141. Thus, there is no need to provide a filter circuit between the low noise amplifier 142 and the output switch 160. Thus, the number of filter circuits in the power amplifier module 100a can be reduced. Therefore, the size of the module can be reduced.

In contrast, in the case where a filter circuit is provided on the output terminals 162 side of the output switch 160, a filter circuit needs to be provided for each of the output terminals 162. This is because a second-order harmonic wave of BAND 8 output from the low noise amplifier 141 needs to be attenuated at each of the output terminals 162. That is, with the configuration of the power amplifier module 100a in which the filter circuit 150 is provided between the output switch 160 and the low noise amplifier 140, the number of filter circuits can be reduced.

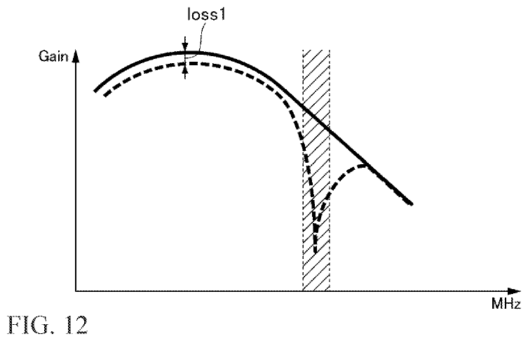

Loss of the signal S1 in the case where a filter circuit is provided on an output terminal side of an output switch will be described with reference to FIG. 12. FIG. 12 is a graph illustrating an example of loss of the signal S1 in the case where a filter circuit is provided on an output terminal side of an output switch. In FIG. 12, an x axis represents frequency, and a y axis represents gain. Explanation will be provided with reference to FIG. 4 in an appropriate manner. As described above, in the case where a filter circuit is provided on the output terminals 162 side of the output switch 160, filter circuits need to be provided for all the output terminals 162. Thus, as illustrated in FIG. 12, compared to the case where no filter circuit is provided for the output terminals 162 (a solid line in FIG. 12), loss (loss1 in FIG. 12) in a signal (a broken line in FIG. 12) output from the low noise amplifier 141 is generated by the filter circuits provided for the output terminals 162. That is, with the configuration of the power amplifier module 100a in which the filter circuit 150 is provided between the output switch 160 and the low noise amplifier 140, loss can be reduced.

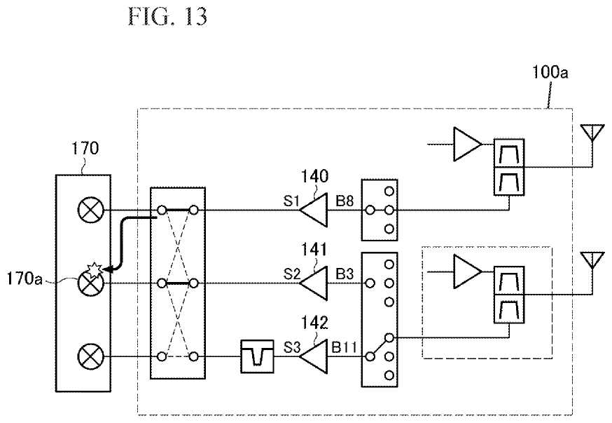

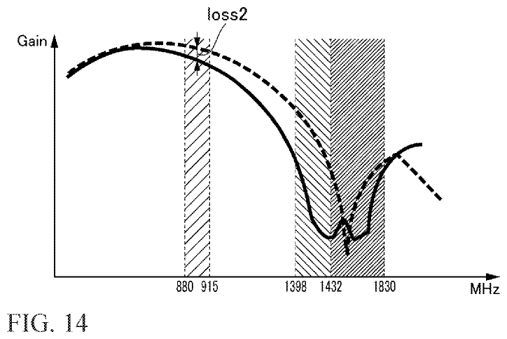

An effect that occurs in the case a filter circuit is not provided at an appropriate position will be described with reference to FIG. 13. FIG. 13 is a diagram illustrating an example of the power amplifier module 100a in which a filter circuit is not provided at an appropriate position. As illustrated in FIG. 13, for example, in the case where the filter circuit 150 is not provided for the low noise amplifier 140 in the power amplifier module 100a, the characteristics of a mixer 170a for BAND 3 in the high-frequency integrated circuit 170 are deteriorated by a second-order harmonic wave of BAND 8. That is, in the case where the power amplifier module 100a is configured such that a filter circuit is properly provided between the output switch 160 and the low noise amplifier 140, deterioration of the characteristics of the high-frequency integrated circuit 170 can be prevented.

A filter circuit in the power amplifier module 100a may be configured to attenuate high-order harmonic waves from the amplifier 110 and the amplifier 111. Specifically, the filter circuit 151 may be configured to, in the case where the amplifier 110 transmits a signal of BAND 8 (for example, 880 MHz to 915 MHz in the transmission band), attenuate a signal of a frequency band (for example, 1760 MHz to 1830 MHz) of a high-order harmonic wave that is an integral multiple of the transmission band of BAND 8.

### Second Modification

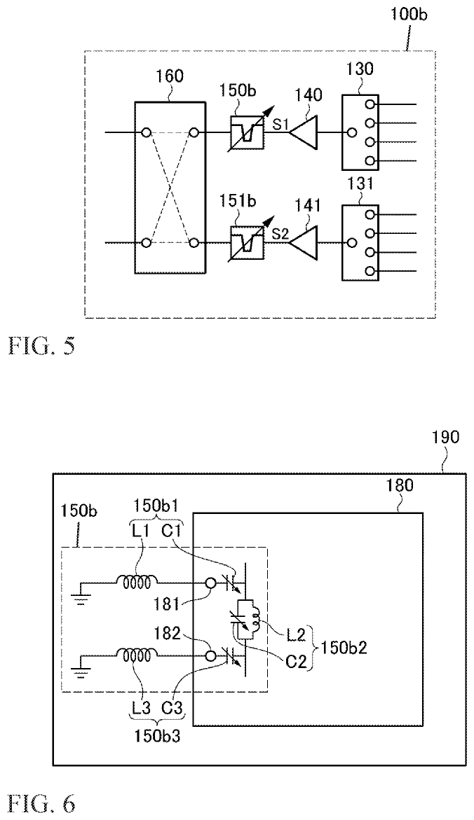

Next, a power amplifier module 100b according to a second modification will be described with reference to FIGS. 5 and 6. FIG. 5 is a diagram illustrating part of a configuration of the power amplifier module 100b according to the second modification. FIG. 6 is a diagram illustrating an example of a configuration of a filter circuit 150b in the second modification. As illustrated in FIG. 5, the power amplifier module 100b is different from the power amplifier module 100 according to the first embodiment in that the power amplifier module 100b includes filter circuits 150b and 151b that are capable of varying frequency bands to be attenuated. Hereinafter, for example, frequency bands of the signal S1 output from the low noise amplifier 140 and the signal S2 output from the low noise amplifier 141 range from 600 MHz to 1000 MHz (for example, a full low band). Hereinafter, only features different from the power amplifier module 100 will be described.

Explanation for the filter circuit 151b, which has a configuration similar to the configuration of the filter circuit 150b, will be omitted.

The filter circuit 150b is, for example, a filter that varies a frequency band to be attenuated. For example, the filter circuit 150b varies, in accordance with the signal S1, a frequency band to be attenuated. In other words, for example, the filter circuit 150b may vary, in accordance with an operation of the input switch 130, a frequency band to be attenuated.

A configuration of the filter circuit 150b will be described with reference to FIG. 6. For example, the filter circuit 150b may be configured to include a combination of a plurality of resonant circuits. Specifically, as illustrated in FIG. 6, the filter circuit 150b includes, for example, a first resonant circuit 150b1, a second resonant circuit 150b2, and a third resonant circuit 150b3. The first resonant circuit 150b1 includes a variable capacitor C1 and an inductor L1 connected in series with the variable capacitor C1, and one end of the first resonant circuit 150b1 is connected to the ground. The second resonant circuit 150b2 includes a variable capacitor C2 and an inductor L2 connected in parallel with the variable capacitor C2. The third resonant circuit 150b3 includes a variable capacitor C3 and an inductor L3 connected in series with the variable capacitor C3, and one end of the third resonant circuit 150b3 is connected to the ground. The filter circuit 150b adjusts the variable capacitors C1 to C3 to vary a frequency band to be attenuated.

Furthermore, as illustrated in FIG. 6, part of elements configuring the filter circuit 150b may be provided in a module different from a module in which the low noise amplifier 140 is provided. Specifically, as illustrated in FIG. 6, in the filter circuit 150b, the inductor L1 and the inductor L3 may be provided, through terminals 181 and 182 from a module 180 in which the low noise amplifier 140 is provided, at a substrate 190 on which the module 180 is mounted. Thus, the size of the power amplifier module 100b can be reduced. The inductor L1 and the inductor L3 may be provided on a surface of the substrate 190 or may be provided inside the substrate 190. Furthermore, at least one of the inductor L1 and the inductor L3 may be provided at the substrate 190.

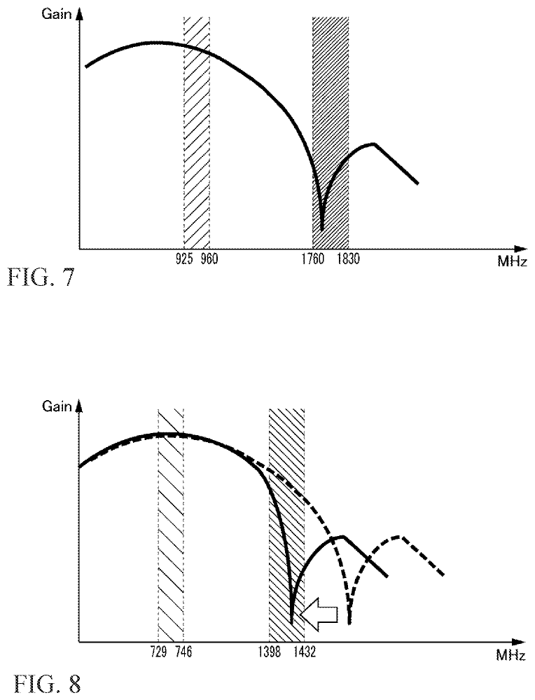

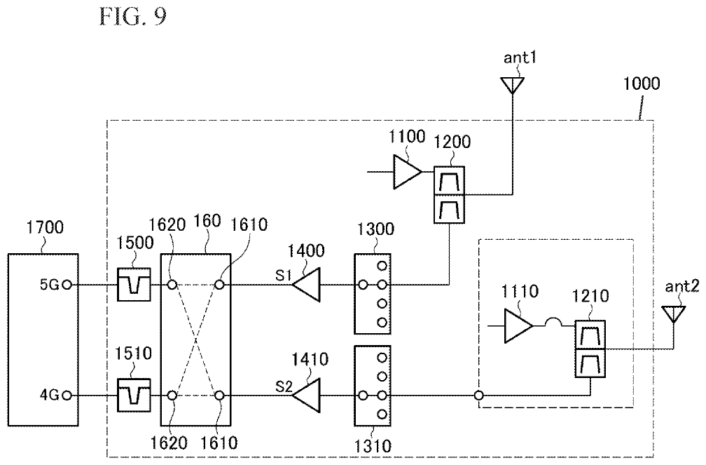

Next, effectiveness of adjustment of a frequency band to be attenuated by the filter circuit 150b will be described with reference to FIGS. 7, 8, and 14. FIG. 7 is a graph illustrating an example of attenuation of a second-order harmonic wave of the transmission band of BAND 8 included in the signal S1 in the filter circuit 150b. FIG. 8 is a graph illustrating an example of attenuation of a second-order harmonic wave of the transmission band of BAND 12 included in the signal S1 in the filter circuit 150b. FIG. 14 illustrates attenuation of second-order harmonic waves of the signal S1 in the transmission bands of BAND 8 and BAND 12 in the filter circuit 150 that is not capable of adjusting a frequency band to be attenuated. In FIGS. 7, 8, and 14, an x axis represents frequency, and a y axis represents gain.

As illustrated in FIG. 7, in the case where a use frequency band of the low noise amplifier 140 is the reception band of BAND 8 (925 MHz to 960 MHz), the signal S1 may contain a signal of the transmission band of BAND 8 (880 MHz to 915 MHz). The filter circuit 150b is adjusted to attenuate a second-order harmonic wave (1760 MHz to 1830 MHz) of the transmission band of BAND 8 (880 MHz to 915 MHz) (see a solid line in FIG. 7). As illustrated in FIG. 8, in the case where a use frequency band of the low noise amplifier 140 is the reception band of BAND 12 (729 MHz to 746 MHz), the signal S1 may contain a signal of the transmission band of BAND 12 (699 MHz to 716 MHz). The filter circuit 150b is adjusted to attenuate a second-order harmonic wave (1398 MHz to 1492 MHz) of the transmission band of BAND 12 (see a solid line in FIG. 8).

In contrast, as illustrated in FIG. 14, in the case where the filter circuit 150b is a filter circuit that is not capable of adjusting a frequency band to be attenuated, the filter circuit 150b is configured to attenuate a second-order harmonic wave of the transmission band of BAND 8 and a second-order harmonic wave of the transmission band of BAND 12. In this case, to perform filtering of the signal S1 of BAND 8, the filter circuit 150b also attenuates a frequency band corresponding to the second-order harmonic wave of BAND 12. Thus, loss indicated as “loss2” in FIG. 14 occurs in the signal S1. That is, with the provision of the filter circuit 150b that is capable of adjusting a frequency band to be attenuated, loss of the signal S1 can be reduced.

Although the configuration in which the filter circuit 150b is provided for the low noise amplifier 140 and the filter circuit 151b is provided for the low noise amplifier 141 has been described above, the configuration is not limited to that described above. For example, a filter circuit that is capable of adjusting a frequency band to be attenuated may be provided for at least one of the low noise amplifier 140 and the low noise amplifier 141. Specifically, in the case where the low noise amplifier 140 supports frequency bands of BAND 8, BAND 26, and BAND 20 and the low noise amplifier 141 supports a frequency band of BAND 28, the filter circuit 150b that is capable of adjusting a frequency band to be attenuated may be provided only for the low noise amplifier 140. Thus, with the provision of the filter circuit 150b only for a low noise amplifier that amplifies signals over a wide frequency range, the size of the power amplifier module 100b can be reduced.

Power amplifier module 200 according to second embodiment

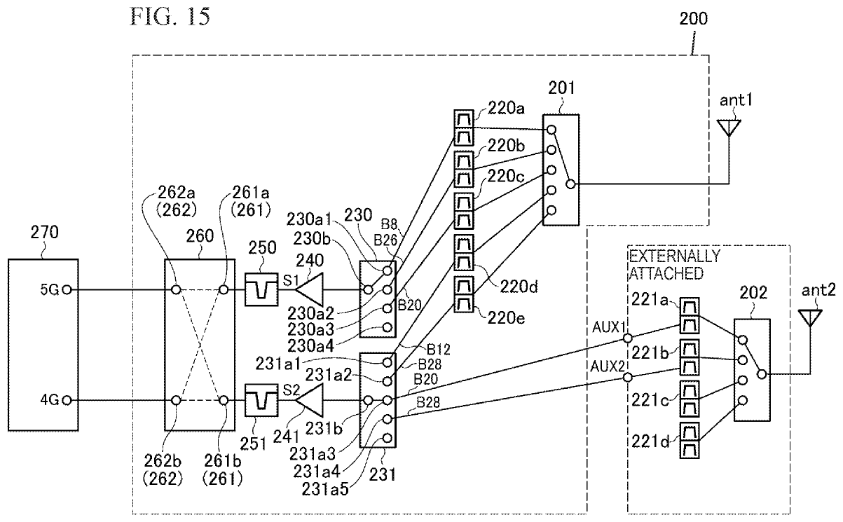

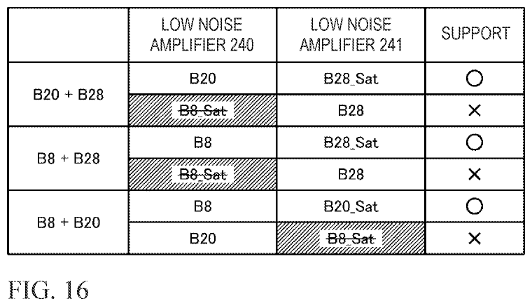

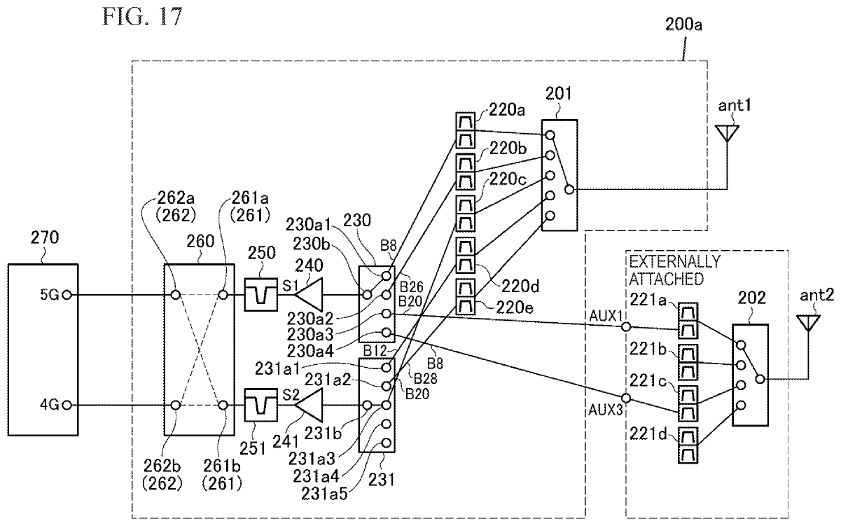

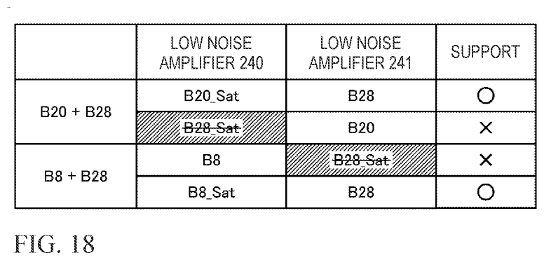

An overview of a power amplifier module 200 according to a second embodiment will be described with reference to FIGS. 15 to 18. FIG. 15 is a diagram illustrating an overview of a configuration of the power amplifier module 200 according to the second embodiment. FIG. 16 is a table illustrating an example of a combination of frequency bands in the second embodiment. FIG. 17 is a diagram illustrating an overview of a configuration of a power amplifier module 200a according to a first comparative example. FIG. 18 is a table illustrating an example of a combination of frequency bands in the first comparative example. The power amplifier module 200 is different from the power amplifier module 100 according to the first embodiment in that a predetermined combination of a frequency band of a signal that transmits through a low noise amplifier 240 and a frequency band of a signal that transmits through a low noise amplifier 241 is used so that the size of the module can be reduced.

Hereinafter, for example, in FIGS. 15 and 16, the first antenna ant1 receives signals of BAND 8 (925 MHz to 960 MHz in the reception band), BAND 12 (729 MHz to 746 MHz in the reception band), BAND 20 (791 MHz to 821 MHz in the reception band), BAND 26 (859 MHz to 894 MHz in the reception band), and BAND 28 (758 MHz to 803 MHz in the reception band), and the second antenna ant2 receives signals of BAND 20 and BAND 8. A switch 202 connected to the second antenna ant2 and duplexers 221 are provided in a module different from other components of the power amplifier module 200. Furthermore, for example, in FIGS. 17 and 18, the first antenna ant1 receives signals of BAND 8, BAND 12, BAND 20, BAND 26, and BAND 28, and the second antenna ant2, which is externally attached, receives signals of BAND 20 and BAND 8. Furthermore, the power amplifier module 200 according to the second embodiment implements, regarding combinations of a frequency band of the signal S1 output from the low noise amplifier 240 and a frequency band of the signal S2 output from the low noise amplifier 241, EN-DC based on a combination of BAND 20 and BAND 28 (hereinafter, referred to as “first EN-DC”) and EN-DC based on a combination of BAND 8 and BAND 28 (hereinafter, referred to as “second EN-DC”). To implement these combinations, BAND 20 and BAND 28 need to be received at different antennas, and BAND 8 and BAND 28 need to be received at different antennas.

The configuration of the power amplifier module 200 will be described with reference to FIG. 15. As illustrated in FIG. 15, in the power amplifier module 200, the signal S1 received at the first antenna ant1 is input, through a switch 201 that switches between paths depending on the frequency band of the signal S1, to a duplexer 220 (for example, duplexers 220a, 220b, 220c, 220d, or 220e). The duplexer 220a splits a signal of BAND 8 into transmission and reception signals. The duplexer 220b splits a signal of BAND 26 into transmission and reception signals. The duplexer 220c splits a signal of BAND 20 into transmission and reception signals. The duplexer 220d splits a signal of BAND 12 into transmission and reception signals. The duplexer 220e splits a signal of BAND 28 into transmission and reception signals. The duplexer 220a is connected to an input terminal 230a1 of an input switch 230. The duplexer 220b is connected to an input terminal 230a2 of the input switch 230. The duplexer 220c is connected to an input terminal 230a3 of the input switch 230. The duplexer 220d is connected to an input terminal 231a1 of an input switch 231. The duplexer 220e is connected to an input terminal 231a2 of the input switch 231.

Furthermore, in the power amplifier module 200, the signal S2 received at the second antenna ant2 is input, through a switch 202 that switches between paths depending on the frequency band of the signal S2, to a duplexer 221 (for example, a duplexer 221a, 221b, 221c, or 221d). The duplexer 221a splits a signal of BAND 20 into transmission and reception signals. The duplexer 221b splits a signal of BAND 28 into transmission and reception signals. The duplexer 221a is connected to an input terminal 231a3 with an external terminal AUX1 interposed therebetween. The duplexer 221b is connected to an input terminal 231a4 of the input switch 231 with an external terminal AUX2 interposed therebetween.

That is, in FIG. 15, the input switch 230 only needs to include the input terminal 230a3 to which a signal of the first frequency band (for example, BAND 20) is input and the input terminal 230a1 to which a signal of a second frequency band (for example, BAND 8) that is higher than the first frequency band is input. Furthermore, the input switch 231 only needs to include an input terminal 231a4 to which a signal of a third frequency band (for example, BAND 28) is input through the external terminal AUX2. In this example, the first frequency band (for example, 791 MHz to 821 MHz in the reception band) of the signal input to the input switch 230 includes part of the third frequency band (for example, 758 MHz to 803 MHz) of the signal input to the input switch 231.

Combinations of frequency bands used in the power amplifier module 200 for implementing first CA (a combination of BAND 20 and BAND 28) and second EN-DC (a combination of BAND 8 and BAND 28) will be described with reference to FIG. 16. As illustrated in FIG. 16, in the power amplifier module 200, for example, to implement the first CA, the signal S1 of BAND 20 is output from the low noise amplifier 240, and the signal S2 of BAND 28 is output from the low noise amplifier 241 through the external terminal AUX2. Furthermore, in the power amplifier module 200, for example, to implement the second CA, the signal S1 of BAND 8 is output from the low noise amplifier 240, and the signal S2 of BAND 28 is output from the low noise amplifier 241 through the external terminal AUX2. Thus, in the power amplifier module 200, the first EN-DC and the second EN-DC can be implemented using a single duplexer for signals input through the second antenna ant2. Therefore, the size of the module can be reduced.

The configuration of the power amplifier module 200a according to the first comparative example will now be described with reference to FIG. 17. As illustrated in FIG. 17, the power amplifier module 200a is different from the power amplifier module 200 in that the duplexer 220c is connected to the input terminal 231a3 of the input switch 231, the duplexer 221a is connected to the input terminal 230a3 of the input switch 230 with the external terminal AUX1 interposed therebetween, and the duplexer 221c is connected to the input terminal 230a4 of the input switch 230 with an external terminal AUX3 interposed therebetween. The duplexer 221c splits a signal of BAND 8 into transmission and reception signals. In the power amplifier module 200a, to implement the first EN-DC and the second EN-DC, two duplexers for signals input through the second antenna ant2 are required. Thus, the size of the module increases.

Combinations of frequency bands used in the power amplifier module 200a for implementing the first EN-DC (a combination of BAND 20 and BAND 28) and the second EN-DC (a combination of BAND 8 and BAND 28) will be described with reference to FIG. 18. As illustrated in FIG. 18, in the power amplifier module 200a, for example, to implement the first EN-DC, the signal S1 of BAND 20 is output from the low noise amplifier 240 through the external terminal AUX1, and the signal S2 of BAND 28 is output from the low noise amplifier 241 through the duplexer 220e. Furthermore, in the power amplifier module 200a, for example, to implement the second EN-DC, the signal S1 of BAND 8 is output from the low noise amplifier 240 through the external terminal AUX3, and the signal S2 of BAND 28 is output from the low noise amplifier 241 through the duplexer 220e. As described above, in the power amplifier module 200, two duplexers for signals input through the second antenna ant2 are required. Thus, the size of the module increases.

Next, the power amplifier module 200 for the case where the first EN-DC, the second EN-DC, and carrier aggregation based on the combination of BAND 8 and BAND 20 (hereinafter, referred to as “third EN-DC”) are implemented will be described with reference to FIGS. 15, 16, 19, and 20. After that, size reduction of the power amplifier module 200 will be described by comparing the power amplifier module 200 with a power amplifier module 200b according to a second comparative example. Explanation for the features of the power amplifier module 200 described above will be omitted in an appropriate manner.

As illustrated in FIG. 15, in the power amplifier module 200 that implements the first EN-DC, the second EN-DC, and the third EN-DC, the input switch 230 only needs to include the input terminal 230a3 to which a signal of the first frequency band (for example, BAND 20) is input and the input terminal 230a1 to which a signal of the second frequency band (for example, BAND 8) that is higher than the first frequency band is input. Furthermore, the input switch 231 only needs to include the input terminal 231a4 to which a signal of the third frequency band (for example, BAND 28) is input through the external terminal AUX2 and the input terminal 231a3 to which a signal of the first frequency band (for example, BAND 20) is input through the external terminal AUX1. Thus, the power amplifier module 200 is capable of receiving signals of different frequency bands based on a combination of the first frequency band and the third frequency band, a combination of the second frequency band and the third frequency band, and a combination of the first frequency band and the second frequency band at the same time. Being capable of receiving signals of different frequency bands at the same time may include a case where only the power amplifier module 200 is used or a case where a plurality of modules including a module different from the power amplifier module 200 are used.

Combinations of frequency bands used in the power amplifier module 200 for implementing the first EN-DC (for example, a combination of BAND 20 and BAND 28), the second EN-DC (for example, a combination of the BAND 8 and BAND 28), and the third EN-DC (for example, a combination of BAND 8 and BAND 20) will be described with reference to FIG. 16. As illustrated in FIG. 16, in the power amplifier module 200, for example, to implement the first EN-DC, the signal S1 of BAND 20 is output from the low noise amplifier 240, and the signal S2 of BAND 28 is output from the low noise amplifier 241 through the external terminal AUX2. Furthermore, in the power amplifier module 200, for example, to implement the second EN-DC, the signal S1 of BAND 8 is output from the low noise amplifier 240, and the signal S2 of BAND 28 is output from the low noise amplifier 241 through the external terminal AUX2. Furthermore, in the power amplifier module 200, for example, to implement the third EN-DC, the signal S1 of BAND 8 is output from the low noise amplifier 240, and the signal S2 of BAND 20 is output from the low noise amplifier 241 through the external terminal AUX1. That is, the power amplifier module 200 implements the first EN-DC, the second EN-DC, and the third EN-DC by using two duplexers for signals input through the second antenna ant2. Thus, the size of the module can be reduced.

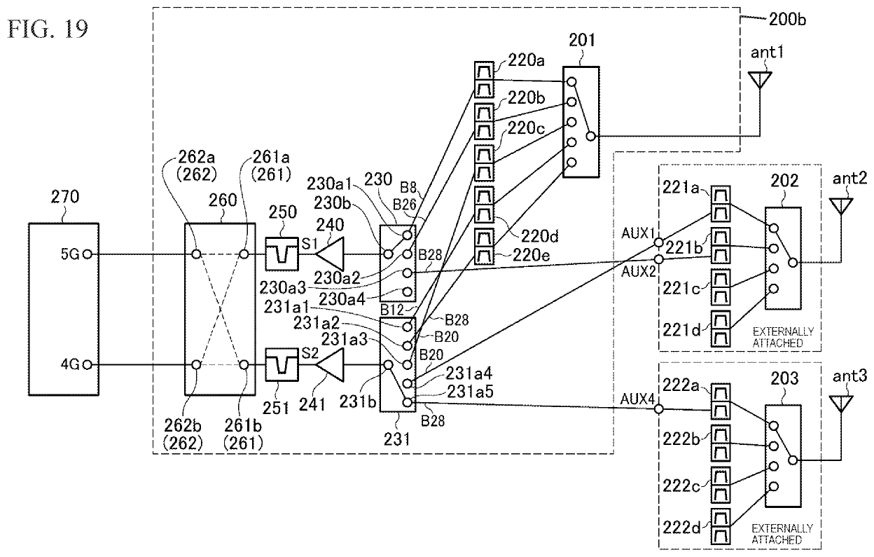

The configuration of the power amplifier module 200b according to the second comparative example will now be described with reference to FIG. 19. FIG. 19 is a diagram illustrating an overview of the configuration of the power amplifier module 200b according to the second comparative example. As illustrated in FIG. 19, the power amplifier module 200b is different from the power amplifier module 200 in that the duplexer 220c is connected to the input terminal 231a3 of the input switch 231, the duplexer 221a is connected to the input terminal 231a4 of the input switch 231 with the external terminal AUX1 interposed therebetween, and the duplexer 221b is connected to the input terminal 230a3 of the input switch 230 with the external terminal AUX2 interposed therebetween. Furthermore, a signal of BAND 28 is input, through a switch 203 connected to an antenna ant3 and a duplexer 222a, to the power amplifier module 200b. Specifically, the duplexer 222a splits a signal of BAND 28 into transmission and reception signals. The duplexer 222a is connected to an input terminal 231a5 of the input switch 231 with an external terminal AUX4 interposed therebetween. In the power amplifier module 200b, to implement the first EN-DC, the second EN-DC, and the third EN-DC, three duplexers for signals input through the antenna ant2 and the antenna ant3 are required. Thus, the size of the module increases.

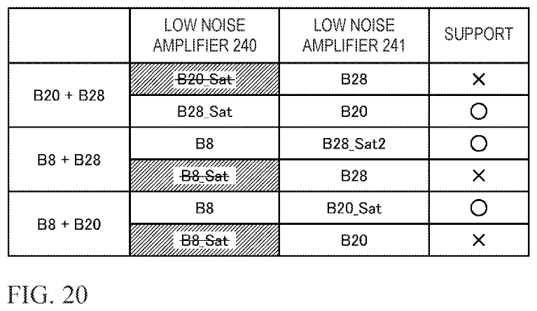

Combinations of frequency bands used in the power amplifier module 200b for implementing the first EN-DC (for example, a combination of BAND 20 and BAND 28), the second EN-DC (for example, a combination of BAND 8 and BAND 28), and the third EN-DC (for example, a combination of BAND 8 and BAND 20) will be described with reference to FIG. 20. FIG. 20 is a table illustrating an example of combinations of frequency bands in the second comparative example. As illustrated in FIG. 20, in the power amplifier module 200b, for example, to implement the first EN-DC, the signal S1 of BAND 28 is output from the low noise amplifier 240 through the external terminal AUX2, and the signal S2 of BAND 20 is output from the low noise amplifier 241 through the duplexer 220c. Furthermore, in the power amplifier module 200b, for example, to implement the second EN-DC, the signal S1 of BAND 8 is output from the low noise amplifier 240 through the duplexer 220a, and the signal S2 of BAND 28 is output from the low noise amplifier 241 through the external terminal AUX4. Furthermore, in the power amplifier module 200b, for example, to implement the third EN-DC, the signal S1 of BAND 8 is output from the low noise amplifier 240 through the duplexer 220a, and the signal S2 of BAND 20 is output from the low noise amplifier 241 through the external terminal AUX1. As described above, in the power amplifier module 200, three duplexers for signals input through the antenna ant2 and the antenna ant3 are required. Thus, the size of the module increases.

For example, a case where BAND representing a frequency band is expressed as a Downlink frequency band has been described above. However, BAND representing a frequency band may be expressed as an Uplink frequency band. Furthermore, although examples of frequency bands corresponding to the first EN-DC, the second EN-DC, and the third EN-DC have been described above, the frequency bands used are not necessarily limited to the first EN-DC, the second EN-DC, and the third EN-DC and may be applied to carrier aggregation implemented by a combination of desired frequency bands.

### Conclusion

A power amplifier module 100 according to an embodiment includes an output switch 160 that includes a plurality of input terminals 161 and a plurality of output terminals 162 and is capable of electrically connecting each of the plurality of input terminals 161 to at least one of the plurality of output terminals 162; a low noise amplifier 140 (first low noise amplifier) that amplifies a signal of a predetermined frequency band input through an antenna (for example, a first antenna ant1) receiving signals of a plurality of frequency bands and outputs a signal S1 (first signal) to an input terminal 161a (first input terminal) among the plurality of input terminals 161; and a low noise amplifier 141 (second low noise amplifier) that amplifies a signal of a predetermined frequency band input through a second antenna ant2 receiving signals of a plurality of frequency bands and outputs a signal S2 (second signal) to an input terminal 161b (second input terminal) different from the input terminal 161a (first input terminal) among the plurality of input terminals 161. A filter circuit 151 (filter) that attenuates a signal of a frequency band higher than a frequency band of the signal S2 (second signal) is electrically connected between the input terminal 161b (second input terminal) and the low noise amplifier 141 (second low noise amplifier). Thus, the size of a module can be reduced.

Furthermore, in the power amplifier module 100 according to this embodiment, the low noise amplifier 140 (first low noise amplifier) amplifies a signal of a first band (first frequency band) and outputs the signal S1 (first signal). The low noise amplifier 141 (second low noise amplifier) amplifies a signal of a second band (second frequency band) lower than the first band (first frequency band) and outputs the signal S2 (second signal), and the low noise amplifier 141 (second low noise amplifier) is electrically connected to the input terminal 161b (second input terminal) with the filter circuit 151 (filter) interposed therebetween, the filter circuit 151 (filter) attenuating the signal of the frequency band higher than the second band (second frequency band). Thus, the size of the module can be reduced, and loss of a signal can be reduced.

Furthermore, in the power amplifier module 100 according to this embodiment, the low noise amplifier 140 (first low noise amplifier) amplifies a signal of a first reception band included in the first band (first frequency band) input through the antenna and outputs the signal S1 (first signal). The low noise amplifier 141 (second low noise amplifier) amplifies a signal of a second reception band included in the second band (second frequency band) input through the antenna, the second band (second frequency band) being lower than the first band (first frequency band) and outputs the signal S2 (second signal), and the low noise amplifier 141 (second low noise amplifier) is electrically connected to the input terminal 161b (second input terminal) with the filter circuit 151 (filter) interposed therebetween, the filter circuit 151 (filter) attenuating a signal of a frequency band that is an integral multiple of a second transmission band, which is a frequency band of a signal output from an amplifier 111 for transmission included in the second band (second frequency band), the signal attenuated being included in the signal S2 (second signal). Thus, the size of the module can be reduced, and loss of a signal can be reduced.

Furthermore, the power amplifier module 100 according to this embodiment further includes at least one of a filter circuit 150 and the filter circuit 151 (filter). Thus, the size of the module can be reduced, and loss of a signal can be reduced.

Furthermore, in the power amplifier module 100 according to this embodiment, the filter circuit 151 (filter) includes a configuration that varies a frequency band to be attenuated. Thus, the size of the module can be reduced, and loss of a signal can be reduced.

In the power amplifier module 100 according to this embodiment, the filter circuit 150 or the filter circuit 151 (filter) is configured to include a first element that is provided in a same module as a module in which the low noise amplifier 141 (second low noise amplifier) is provided and a second element (for example, an inductor L1 and an inductor L3 illustrated in FIG. 6) that is provided in a module different from the module in which the second low noise amplifier is provided and is electrically connected to the first element with a predetermined terminal interposed therebetween. Thus, the size of the module can be reduced.

Furthermore, in the power amplifier module 100 according to this embodiment, a filter circuit (filter) that attenuates a signal of a predetermined frequency band is not electrically connected between the input terminal 161a (first input terminal) and the low noise amplifier 140 (first low noise amplifier). Thus, the size of the module can be reduced, and loss of a signal can be reduced.

Furthermore, in the power amplifier module 100 according to this embodiment, the low noise amplifier 140 (first low noise amplifier) is connected to the first antenna ant1 with a duplexer 120 (first demultiplexer) that splits a plurality of frequency bands interposed therebetween, and the power amplifier module 100 further includes an amplifier 110 (first amplifier) that is connected to the first antenna ant1 with the duplexer 120 (first demultiplexer) interposed therebetween. Thus, the size of the module can be reduced, and loss of a signal can be reduced.

Furthermore, in the power amplifier module 100 according to this embodiment, the signal S1 (first signal) output from the low noise amplifier 140 (first low noise amplifier) is a signal of any one of a frequency band (third frequency band) corresponding to a fourth generation mobile communication system (4G) and a frequency band (fourth frequency band) corresponding to a fifth generation mobile communication system (5G), and the signal S2 (second signal) output from the low noise amplifier 141 (second low noise amplifier) is a signal of a frequency band different from the frequency band of the signal S1 (first signal) among the frequency band of 4G (third frequency band) and the frequency band of 5G (fourth frequency band). Thus, the size of the module can be reduced, and EN-DC can be achieved.

A power amplifier module 200 according to an embodiment includes a low noise amplifier 240 (first low noise amplifier) that amplifies a first reception signal of a predetermined frequency band input through a first antenna ant1 capable of receiving signals of a plurality of frequency bands and outputs the amplified first reception signal to an input terminal 261a (a predetermined input terminal) among a plurality of input terminals; a low noise amplifier 241 (second low noise amplifier) that amplifies a second reception signal of a predetermined frequency band input through a second antenna ant2 receiving signals of a plurality of frequency bands and outputs the amplified second reception signal to an input terminal 261b different from the input terminal 261a among the plurality of input terminals 261; an input switch 230 (first input switch) that includes an input terminal 230a3 (first input terminal) to which a signal of a first frequency band (for example, BAND 20) is input, an input terminal 230a1 (second input terminal) to which a signal of a second frequency band (for example, ) higher than the first frequency band is input, and an output terminal 230b (first output terminal) connected to the low noise amplifier 240 (first low noise amplifier), the signals input to the input terminal 230a3 (first input terminal) and the input terminal 230a1 (second input terminal) being among the signals received at the antenna (for example, the first antenna ant1) that receives the signals of the plurality of frequency bands and input through duplexers 220a to 220e (demultiplexers) that split a plurality of frequency bands provided in a same module as a module in which an output switch 260 is provided, and is capable of electrically connecting the input terminal 230a3 (first input terminal) or the input terminal 230a1 (second input terminal) to the output terminal 230b (first output terminal); and an input switch 231 (second input switch) that includes an input terminal 231a4 (third input terminal) to which a signal of a third frequency band (for example, BAND 28) lower than the first frequency band is input and an output terminal 231b (second output terminal) connected to the low noise amplifier 241 (second low noise amplifier), the signal input to the input terminal 231a4 (third input terminal) being among the signals received at the antenna (for example, second antenna ant2) that receives the signals of the plurality of frequency bands and input through duplexers 221a to 221d (demultiplexers) that split a plurality of frequency bands provided in a module different from the module in which the output switch 260 is provided, and is capable of electrically connecting the input terminal 231a4 (third input terminal) to the output terminal 231b (second output terminal). The first frequency band includes part of the third frequency band. Thus, the number of duplexers can be reduced. Therefore, the size of a communication apparatus including the power amplifier module 200 can be reduced.

Furthermore, a power amplifier module 200 according to an embodiment includes a low noise amplifier 240 (first low noise amplifier) that amplifies a first reception signal of a predetermined frequency band input through an antenna (for example, a first antenna ant1) receiving signals of a plurality of frequency bands and outputs the amplified first reception signal to an input terminal 261a (a predetermined input terminal) among a plurality of input terminals 261 of an output switch 260; a low noise amplifier 241 (second low noise amplifier) that amplifies a signal S2 of a predetermined frequency band input through an antenna (for example, a second antenna ant2) receiving signals of a plurality of frequency bands and outputs the amplified signal S2 to an input terminal 261b different from the input terminal 261a (the predetermined input terminal) among the plurality of input terminals 261 of the output switch 260; an input switch 230 (first input switch) that includes an input terminal 230a3 (first input terminal) to which a signal of a first frequency band (for example, BAND 20) is input, an input terminal 230a1 (second input terminal) to which a signal of a second frequency band (for example, BAND 8) higher than the first frequency band is input, and an output terminal 230b (first output terminal) connected to the low noise amplifier 240 (first low noise amplifier), the signals input to the input terminal 230a3 (first input terminal) and the input terminal 230a1 (second input terminal) being among the signals received at the first antenna ant1 that receives the signals of the plurality of frequency bands and input through duplexers 220a to 220e (demultiplexers) that split a plurality of frequency bands provided in a same module as a module in which the output switch 260 is provided, and is capable of electrically connecting the input terminal 230a3 (first input terminal) or the input terminal 230a1 (second input terminal) to the output terminal 230b (first output terminal); and an input switch 231 (second input switch) that includes an input terminal 231a4 (third input terminal) to which a signal of a third frequency band (for example, BAND 28) lower than the first frequency band is input, an input terminal 231a3 (fourth input terminal) to which a signal of the first frequency band (for example, BAND 20) is input, and an output terminal 231b (second output terminal) connected to the low noise amplifier 241 (second low noise amplifier), the signals input to the input terminal 231a4 (third input terminal) and the input terminal 231a3 (fourth input terminal) being among the signals received at the second antenna ant2 that is different from the first antenna ant1 and receives the signals of the plurality of frequency bands and input through duplexers 221a to 221d (demultiplexers) that split a plurality of frequency bands provided in a module different from the module in which the output switch 260 is provided, and is capable of electrically connecting the input terminal 231a4 (third input terminal) to the output terminal 231b (second output terminal). Signals of different frequency bands based on a combination of the first frequency band and the third frequency band, a combination of the second frequency band and the third frequency band, and a combination of the first frequency band and the second frequency band are able to be received at the same time. Thus, the number of duplexers can be reduced. Therefore, the size of a communication apparatus including the power amplifier module 200 can be reduced.

Furthermore, in the power amplifier module 200 according to this embodiment, the first frequency band is a frequency band of BAND 20. Thus, the number of duplexers can be reduced. Therefore, the size of a communication apparatus including the power amplifier module 200 can be reduced.

Furthermore, in the power amplifier module 200 according to this embodiment, the second frequency band is a frequency band of BAND 8, and the third frequency band is a frequency band of BAND 28. Thus, the number of duplexers can be reduced. Therefore, the size of a communication apparatus including the power amplifier module 200 can be reduced.

The power amplifier module 200 according to this embodiment further includes the plurality of input terminals 261, a plurality of output terminals 262, and the output switch 260 that is capable of electrically connecting each of the plurality of input terminals 261 to at least one of the plurality of output terminals 262. Thus, the size of the module can be reduced, and EN-DC can be implemented.

The embodiments described above are intended to facilitate understanding of the present disclosure, and are not intended to limit interpretation of the present disclosure. The present disclosure may be modified or improved without necessarily departing from the spirit and scope of the disclosure, and equivalents thereof are also included in the present disclosure. That is, an embodiment for which design is changed as appropriate by a person skilled in the art is also included in the scope of the present disclosure as long as the features of the present disclosure are included. Elements included in an embodiment and the arrangement of the elements are not limited to illustrated ones and may be changed as appropriate.

What is claimed is:

1. A power amplifier module comprising:
an output switch that includes a plurality of input terminals and a plurality of output terminals, and that is configured to electrically connect each of the plurality of input terminals to at least one of the plurality of output terminals;
a first low noise amplifier configured to amplify a signal of a first frequency band and to output a first signal to a first input terminal among the plurality of input terminals, the signal of the first frequency band being input through a first antenna that receives signals of a plurality of frequency bands;
a second low noise amplifier configured to amplify a signal of a second frequency band and to output a second signal to a second input terminal different from the first input terminal among the plurality of input terminals, the signal of the second frequency band being input through a second antenna that receives signals of another plurality of frequency bands; and
wherein a filter is electrically connected between the second input terminal and the second low noise amplifier, the filter being configured to attenuate a signal of a frequency band higher than the second signal.

2. The power amplifier module according to claim 1,
wherein the second frequency band is lower than the first frequency band, and
wherein the second low noise amplifier is electrically connected to the second input terminal with the filter interposed therebetween.

3. The power amplifier module according to claim 2,
wherein the signal of the first frequency band is of a first reception band included in the first frequency band,
wherein the signal of the second frequency band is of a second reception band included in the second frequency band,
wherein the second low noise amplifier is electrically connected to the second input terminal with the filter interposed therebetween, and
wherein the filter is configured to attenuate a portion of the second signal in a frequency band that is an integral multiple of a transmission band, the transmission band being a frequency band of a signal output from a transmission amplifier and being included in the second frequency band, the signal attenuated being included in the second signal.

4. The power amplifier module according to claim 2, further comprising the filter.

5. The power amplifier module according to claim 4, wherein the filter is configured to have a variable attenuation band.

6. The power amplifier module according to claim 5, wherein the filter comprises a first circuit element that is in a same module as the second low noise amplifier, and a second circuit element that is in a module different from the module comprising the first circuit element and the second low noise amplifier, and
wherein the second circuit element is electrically connected to the first element with a predetermined terminal interposed therebetween.

7. The power amplifier module according to claim 1,
wherein the first low noise amplifier is connected to the first antenna with a first demultiplexer interposed therebetween, and
wherein the power amplifier module further comprises a first amplifier that is connected to the first antenna with the first demultiplexer interposed therebetween.

8. The power amplifier module according to claim 1,
wherein the first signal is of a third frequency band corresponding to a fourth generation mobile communication system or a fourth frequency band corresponding to a fifth generation mobile communication system, and
wherein the second signal is of a frequency band different from the frequency band of the first signal among the third frequency band and the fourth frequency band.

9. The power amplifier module according to claim 1, wherein the plurality of frequency bands received by the first antenna include one or more of the same frequency bands as the another plurality of frequency bands received by the second antenna.

10. A power amplifier module comprising:
a first low noise amplifier configured to amplify a first reception signal of a first predetermined frequency band and to output an amplified first reception signal to a first predetermined input terminal, the first reception signal being input through a first antenna that receives signals of a plurality of frequency bands, and the first predetermined input terminal being among a plurality of input terminals of an output switch;
a second low noise amplifier configured to amplify a second reception signal of a second predetermined frequency band and to output an amplified second reception signal to a second predetermined input terminal, the second reception signal being input through a second antenna that receives signals of another plurality of frequency bands, and the second predetermined input terminal being different from the first predetermined input terminal among the plurality of input terminals of the output switch;
a first input switch that includes a first input terminal to which a signal of a first frequency band is input, a second input terminal to which a signal of a second frequency band higher than the first frequency band is input, and a first output terminal connected to the first low noise amplifier; and
a second input switch that includes a third input terminal to which a signal of a third frequency band lower than the first frequency band is input and a second output terminal connected to the second low noise amplifier,
wherein the signals input to the first input terminal and the second input terminal are among the signals received at the first antenna and are input through a first demultiplexer,
wherein the first demultiplexer is configured to electrically connect the first input terminal or the second input terminal to the first output terminal,
wherein the first demultiplexer is in a same module as the output switch,
wherein the signal input to the third input terminal is among the signals received at the second antenna and is input through a second demultiplexer,
wherein the second demultiplexer is in a module different from the module comprising the output switch,
wherein the second demultiplexer is configured to electrically connect the third input terminal to the second output terminal, and
wherein the first frequency band includes part of the third frequency band.

11. The power amplifier module according to claim 10, wherein the plurality of frequency bands received by the first antenna include one or more of the same frequency bands as the another plurality of frequency bands received by the second antenna.

12. A power amplifier module comprising:
a first low noise amplifier configured to amplify a first reception signal of a first predetermined frequency band and to output an amplified first reception signal to a predetermined input terminal, the first reception signal being input through a first antenna that receives signals of a plurality of frequency bands, and the first predetermined input terminal being among a plurality of input terminals of an output switch;
a second low noise amplifier configured to amplify a second reception signal of a second predetermined frequency band and to output an amplified second reception signal to a second predetermined input terminal, the second reception signal being input through a second antenna that receives signals of another plurality of frequency bands, and the second predetermined input terminal being different from the first predetermined input terminal among the plurality of input terminals of the output switch;
a first switch that includes a first input terminal to which a signal of a first frequency band is input, a second input terminal to which a signal of a second frequency band higher than the first frequency band is input, and a first output terminal connected to the first low noise amplifier; and
a second input switch that includes a third input terminal to which a signal of a third frequency band lower than the first frequency band is input, a fourth input terminal to which a signal of the first frequency band is input, and a second output terminal connected to the second low noise amplifier,
wherein the signals input to the first input terminal and the second input terminal are among the signals received at the first antenna and are input through a first demultiplexer,
wherein the first demultiplexer is configured to electrically connect the first input terminal or the second input terminal to the first output terminal,
wherein the first demultiplexer is in a same module as the output switch,
wherein the signals input to the third input terminal and the fourth input terminal are among the signals received at the second antenna and are input through a second demultiplexer,
wherein the second demultiplexer is in a module different from the module comprising the output switch,
wherein the second demultiplexer is configured to electrically connect the third input terminal to the second output terminal, and
wherein signals of different frequency bands based on a combination of the first frequency band and the third frequency band, a combination of the second frequency band and the third frequency band, and a combination of the first frequency band and the second frequency band, are received at the same time.

13. The power amplifier module according to claim 12, wherein the plurality of frequency bands received by the first antenna include one or more of the same frequency bands as the another plurality of frequency bands received by the second antenna.

14. The power amplifier module according to claim 10, wherein the first frequency band is a frequency band of BAND 20.

15. The power amplifier module according to claim 12, wherein the first frequency band is a frequency band of BAND 20.

16. The power amplifier module according to claim 10,
wherein the second frequency band is a frequency band of BAND 8, and
wherein the third frequency band is a frequency band of BAND 28.

17. The power amplifier module according to claim 12,
wherein the second frequency band is a frequency band of BAND 8, and
wherein the third frequency band is a frequency band of BAND 28.

18. The power amplifier module according to claim 10, further comprising the plurality of input terminals, a plurality of output terminals, and the output switch.

19. The power amplifier module according to claim 12, further comprising the plurality of input terminals, a plurality of output terminals, and the output switch.
